(19) United States
(12) Patent Application Publication
(10) Pub. No.: US 2026/0271305 A1
(43) Pub. Date: Sep. 10, 2026

(54) MAGNETIC MEMORY DEVICE

(71) Applicant: SAMSUNG ELECTRONICS CO., LTD., Suwon-si (KR)

(72) Inventor: Hyung Jong JEONG, Suwon-si (KR)

(73) Assignee: SAMSUNG ELECTRONICS CO., LTD., Suwon-si (KR)

(21) Appl. No.: 19/461,986

(22) Filed: Jan. 28, 2026

(30) Foreign Application Priority Data
Mar. 10, 2025 (KR) 10-2025-0030621

(51) Int. Cl. H10B 61/00; H10B 80/00; H10D 80/30; H10N 50/10; H10N 50/80; H10W 20/20; H10W 20/41; H10W 72/90; H10W 80/00; H10W 90/00

(52) U.S. Cl. CPC H10B 61/10; H10B 80/00; H10D 80/30; H10N 50/10; H10N 50/80; H10W 20/213; H10W 20/435; H10W 72/9226; H10W 72/952; H10W 90/792; H10W 80/312

(57) ABSTRACT

A magnetic memory device may include a first semiconductor structure having a first bonding structure, and a second semiconductor structure disposed on the first semiconductor structure and having a second bonding structure bonded to the first bonding structure. The second semiconductor structure includes a memory structure including a first electrode layer, a magnetic tunnel junction layer, and a second electrode layer sequentially stacked on the second bonding structure, and a wiring disposed on the memory structure and connected to the second electrode layer. The first semiconductor structure includes a substrate disposed under the first bonding structure, and a transistor disposed on the substrate and electrically connected to the memory structure. The memory structure includes a first area adjacent to the wiring and a second area adjacent to the second bonding structure.

### CROSS-REFERENCE TO RELATED APPLICATION

This application claims priority from Korean Patent Application No. 10-2025-0030621 filed on Mar. 10, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a magnetic memory device.

### 2. Description of Related Art

As an electronic device becomes faster and less power-consuming, a memory device embedded therein also requires fast read/write operations and low operating voltage. A magnetic memory device is being studied as the memory device that satisfies these requirements. The magnetic memory device is nonvolatile and capable of high-speed operation, and thus is receiving attention as a next-generation memory.

As the magnetic memory device becomes increasingly highly integrated, STT-MRAM which stores therein information using the Spin Transfer Torque (STT) phenomenon, is being studied. The STT-MRAM may store therein information by directly applying current to a magnetic tunnel junction element to induce magnetization reversal. The highly integrated STT-MRAM requires high-speed operation and low-current operation.

### SUMMARY

A technical purpose of the present disclosure is to provide a magnetic memory device with improved performance and reliability.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

A magnetic memory device according to some embodiments of the present disclosure includes a first semiconductor structure having a first bonding structure, and a second semiconductor structure disposed on the first semiconductor structure and having a second bonding structure bonded to the first bonding structure, wherein the second semiconductor structure includes a memory structure including a first electrode layer, a magnetic tunnel junction layer, and a second electrode layer sequentially stacked on the second bonding structure, and a wiring disposed on the memory structure and connected to the second electrode layer, wherein the first semiconductor structure includes a substrate disposed under the first bonding structure, and a transistor disposed on the substrate and electrically connected to the memory structure, wherein the memory structure includes a first area adjacent to the wiring and a second area adjacent to the second bonding structure, wherein in a direction parallel to an upper surface of the substrate, a width of the second area is smaller than a width of the first area.

A magnetic memory device according to some other embodiments of the present disclosure includes a substrate having an upper surface extending in a first horizontal direction and a second horizontal direction different from each other, a first semiconductor structure disposed on the substrate, and a second semiconductor structure disposed on the first semiconductor structure, wherein the second semiconductor structure includes a first bonding pad, a memory structure disposed on the first bonding pad and including a first electrode layer in contact with the first bonding pad, a magnetic tunnel junction layer disposed on the first electrode layer, and a second electrode layer disposed on the magnetic tunnel junction layer, and a wiring disposed on the second electrode layer so as to be in contact with the second electrode layer, wherein the first semiconductor structure includes a transistor electrically connected to the memory structure, and a second bonding pad bonded to the first bonding pad, wherein each of a width in the first horizontal direction of the wiring and a width in the first horizontal direction of the first bonding pad decreases as each of the wiring and the first bonding pad extends toward the magnetic tunnel junction layer.

A magnetic memory device according to some other embodiments of the present disclosure includes a substrate having an upper surface extending in a first horizontal direction and a second horizontal direction different from each other, a logic area disposed on the substrate, a memory cell area disposed on the logic area, and a peripheral circuit area disposed on the logic area and different from the memory cell area, wherein the memory cell area includes an upper bonding structure, a memory structure disposed on the upper bonding structure and including a first electrode layer, a magnetic tunnel junction layer, and a second electrode layer sequentially stacked, a bit line disposed on the memory structure and connected to the second electrode layer, a capping film extending along a sidewall of the memory structure, and a mold insulating film disposed on the capping film so as to fill a space between the memory structures, wherein the logic area includes a first transistor disposed on the substrate; and a first lower bonding structure disposed on the first transistor and bonded to the upper bonding structure, wherein the peripheral circuit area includes a second transistor on the substrate, and a second lower bonding structure disposed on the second transistor, wherein a width in the first horizontal direction of the memory structure decreases as the memory structure extends toward the upper surface of the substrate, wherein a width in the first horizontal direction of the mold insulating film increases as the mold insulating film extends toward the upper surface of the substrate.

A method for manufacturing a magnetic memory device according to some embodiments of the present disclosure includes forming a memory structure on a buffer insulating layer, wherein the memory structure includes a first electrode layer, a magnetic tunnel junction layer, and a second electrode layer sequentially stacked, forming a first etch stop film on the second electrode layer, removing the first etch stop film and at least a portion of the memory structure to form a first recess in the memory structure, forming a first bonding pad in the first recess, providing a substrate having a transistor formed thereon, forming a lower wiring structure connected to the transistor, forming a second bonding pad connected to the lower wiring structure, place the first bonding pad and the second bonding pad so as to face each other, and bonding the first bonding pad and the second bonding pad to each other, forming a second etch stop film on the first electrode layer, removing the second etch stop film and at least a portion of the memory structure to form a second recess in the memory structure; and forming a bit line in the second recess.

Specific details of other embodiments are included in the detailed description and drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is a block diagram for illustrating a magnetic memory device according to some embodiments;

FIG. 2 is a block diagram for illustrating the nonvolatile memory of FIG. 1;

FIG. 3 is a diagram illustrating a memory cell array according to some embodiments;

FIG. 4 is an example diagram illustrating a memory cell of the memory cell array of FIG. 3;

FIG. 5 is an example diagram illustrating a variable resistance element according to some embodiments;

FIG. 6 is a plan view of a magnetic memory device according to some embodiments;

FIG. 7 is a cross-sectional view of a magnetic memory device taken along lines A-A and B-B of FIG. 6;

FIG. 8 is a cross-sectional view of the magnetic memory device taken along lines C-C and D-D of FIG. 6;

FIG. 9 is a diagram for illustrating a magnetic memory device according to some embodiments, and corresponds to FIG. 7;

FIG. 10 is a diagram for illustrating a magnetic memory device according to some embodiments, and corresponds to FIG. 7;

FIGS. 11 to 17 are diagrams of intermediate structures corresponding to intermediate steps of a method for manufacturing a magnetic memory device according to some embodiments;

FIG. 18 is a view for illustrating bonding between adjacent ones of a plurality of semiconductor chips in a semiconductor structure according to some embodiments;

FIG. 19 is a plan view illustrating a chip area and a scribe lane area of a semiconductor wafer;

FIG. 20 is a cross-sectional view of a semiconductor structure according to some embodiments;

FIG. 21 is a cross-sectional view of a semiconductor structure according to some embodiments.

### DETAILED DESCRIPTIONS

Hereinafter, embodiments according to the technical idea of the present disclosure will be described with reference to the accompanying drawings.

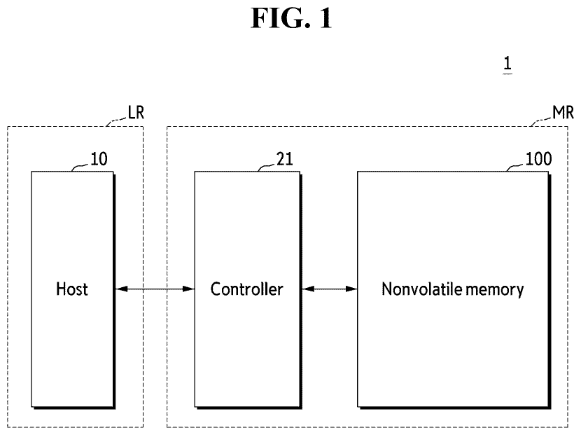

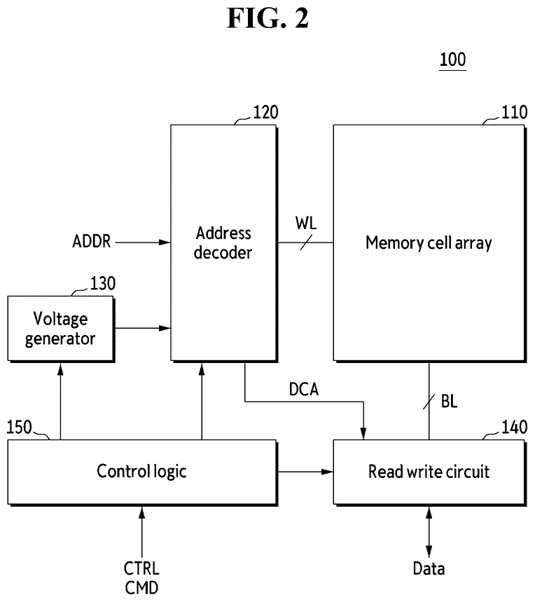

Hereinafter, a magnetic memory device 1 including a nonvolatile memory 100 will be described with reference to FIGS. 1 and 2.

FIG. 1 is a block diagram for illustrating a magnetic memory device according to some embodiments. FIG. 2 is a block diagram for illustrating the nonvolatile memory of FIG. 1.

Referring to FIG. 1, a magnetic memory device 1 may include a logic area LR and a memory area MR The logic area LR may include a host 10, and the memory area MR may include a controller 21 and the nonvolatile memory 100.

In some embodiments, the logic area LR may be connected to the memory area MR via an interface. For example, the logic area LR may transmit a signal to the memory area MR to control the memory area MR In addition, for example, the logic area LR may receive a signal from the memory area MR and process data included in the signal.

For example, the host 10 may include a Central Processing Unit (CPU), a controller, an Application Specific Integrated Circuit (ASIC), etc. Moreover, for example, the host 10 may include a memory chip, such as a dynamic random access memory (DRAM), a static RAM (SRAM), a phase-change RAM (PRAM), a Magneto resistive RAM (MRAM), a ferroelectric RAM (FeRAM), and a resistive RAM (RRAM).

The memory area MR may include the controller 21 and the nonvolatile memory 100. For example, the nonvolatile memory 100 may include a magnetic random access memory (MRAM), a phase-change RAM (PRAM), a resistive RAM (RRAM), etc. However, embodiments according to the technical idea of the present disclosure are not limited thereto. The nonvolatile memory 100 is not limited to a resistive memory and may include various nonvolatile memories such as an Electrically Erasable and Programmable ROM (EPROM), a flash memory, and a ferroelectric RAM (FRAM).

The controller 21 and the nonvolatile memory 100 may be connected to each other via an interface. The controller 21 may access the nonvolatile memory 100. For example, the controller 21 may control a read operation, a write operation, and an erase operation of the nonvolatile memory 100. The controller 21 may serve as an interface between the host 10 and the nonvolatile memory 100. The controller 21 may drive firmware for controlling the nonvolatile memory 100.

The interface between the host 10 and the controller 21 may include various communication standards such as a universal serial bus (USB), a multimedia card (MMC), a peripheral component wiring (PCI), a PCI-express (PCI-E), an advanced technology attachment (ATA), a Serial-ATA, a Parallel-ATA, a small computer small interface (SCSI), an enhanced small disk interface (ESDI), an integrated drive electronics (IDE), a firewire, etc.

The memory area MR may include an embedded MRAM embedded in the magnetic memory device 1. In this regard, the nonvolatile memory 100 of the memory area MR may be embedded in the magnetic memory device 1. Moreover, the nonvolatile memory 100 may be embedded in the logic area LR. However, embodiments of the present disclosure are not limited thereto.

Referring to FIG. 2, the nonvolatile memory 100 may include a memory cell array 110, an address decoder 120, a voltage generator 130, a read write circuit 140, a control logic 150, etc.

The memory cell array 110 may be connected to the address decoder 120 via word lines WL. The memory cell array 110 may be connected to the read write circuit 140 via bit lines BL. The memory cell array 110 may include a plurality of memory cells. For example, memory cells arranged in a row direction may be connected to the word line WL. For example, memory cells arranged in the column direction may be connected to the bit line BL. In this regard, the word line WL may include a read word line or a write word line, and the bit line BL may include a bit line or a sensing line.

The address decoder 120 may be connected to the memory cell array 110 via the word line WL. The address decoder 120 may operate in response to the control of the control logic 150. The address decoder 120 may receive an address ADDR from the controller 21. The address decoder 120 may receive a voltage necessary for each of operations such as programming and reading operations from the voltage generator 130.

The address decoder 120 may decode a row address in the received address ADDR. The address decoder 120 may select the word line WL using the decoded row address. The decoded column address DCA may be provided to the read/write circuit 140. For example, the address decoder 120 may include a row decoder, a column decoder, an address buffer, etc.

The voltage generator 130 may generate a voltage required for an access operation under the control of the control logic 150. For example, the voltage generator 130 may generate a program voltage and a program verification voltage required to perform a program operation. For example, the voltage generator 130 may generate read voltages required to perform a read operation, and may generate an erase voltage and an erase verification voltage required to perform an erase operation. Moreover, the voltage generator 130 may provide the address decoder 120 with a voltage required to perform each operation.

The read/write circuit 140 may be connected to the memory cell array 110 via the bit line BL. The read/write circuit 140 may exchange data Data with the controller 21. The read write circuit 140 may operate in response to the control of the control logic 150. The read/write circuit 140 may receive the decoded column address DCA from the address decoder 120. The read/write circuit 140 may select the bit line BL using the decoded column address DCA.

For example, the read write circuit 140 may program the received data Data in the memory cell array 110. The read write circuit 140 may read data from the memory cell array 110, and may provide the read data to an external device (e.g., the controller 21). For example, the read write circuit 140 may include a sense amplifier, a write driver, a column selection circuit, a page buffer, etc.

The control logic 150 may be connected to the address decoder 120, the voltage generator 130, and the read write circuit 140. The control logic 150 may control an operation of the nonvolatile memory 100. The control logic 150 may operate in response to a control signal CRTL and a command CMD (e.g., a write command and a read command) provided from the controller 21.

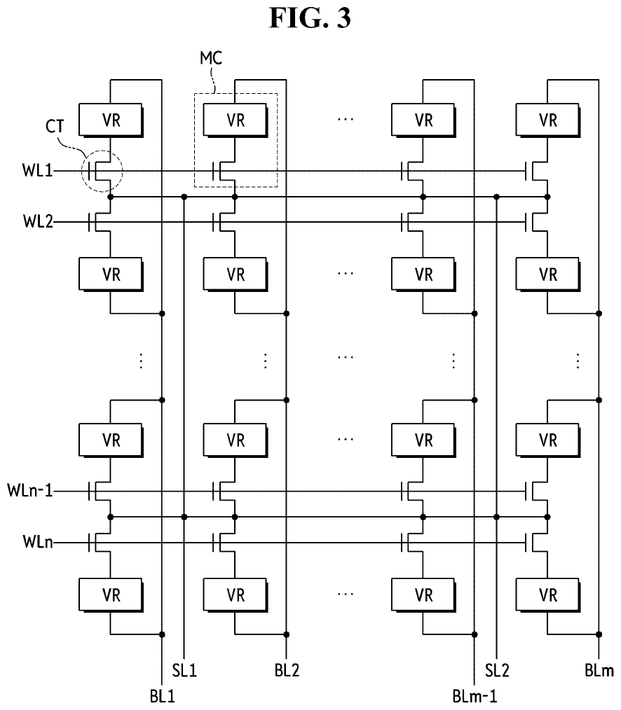

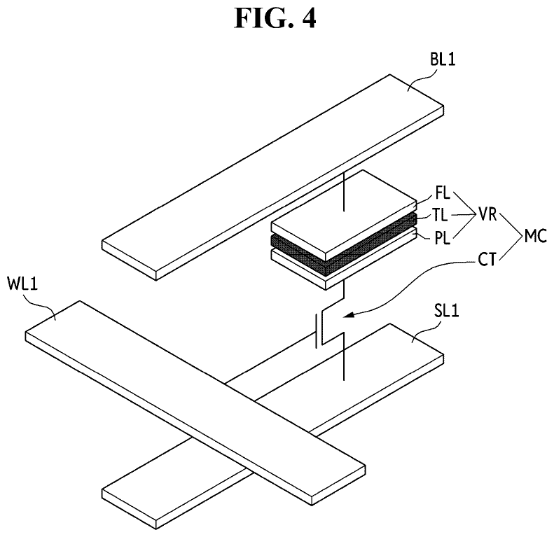

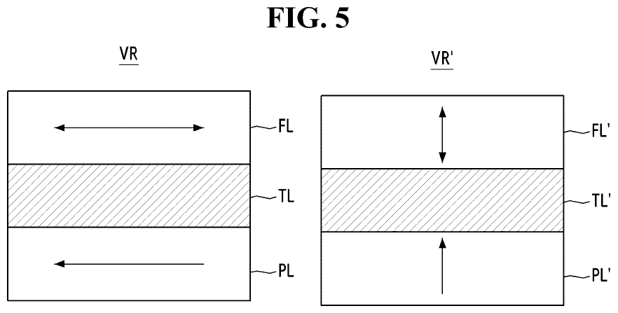

FIG. 3 is a diagram illustrating a memory cell array according to some embodiments. FIG. 4 is an example diagram illustrating a memory cell of the memory cell array of FIG. 3. FIG. 5 is an example diagram illustrating a variable resistance element according to some embodiments.

Referring to FIGS. 3 and 4, the memory cell array 110 may include a plurality of memory cells MC. The memory cells MC may be arranged along a row direction and a column direction. The memory cell MC may include, for example, a variable resistance element VR and a cell transistor CT. In this regard, the memory area MR including the memory cell MC may correspond to MRAM.

A gate of the cell transistor CT may be connected to the word line WL1 to WLn. Gates of the cell transistors CT arranged in the row direction may be commonly connected to one word line (e.g., the first word line WL1). Respective gates of the cell transistors CT of different rows may be connected to different word lines.

One end of the cell transistor CT may be connected to one end of the variable resistance element VR. The other end of the cell transistor CT may be connected to a source line (e.g., a source line SL1 and a source line SL2). The other ends of a pair of cell transistors CT adjacent to each other may be commonly connected to one source line (e.g., the source line SL1).

The other end of the variable resistance element VR may be connected to the bit line BL1 to BLm. The other ends of the variable resistance elements VR arranged in the column direction may be commonly connected to one bit line (e.g., the first bit line BL1).

The variable resistance element VR may have one of a low resistance state and a high resistance state according to a bias condition. Adjusting the state of the variable resistance element VR to one of a low resistance state and a high resistance state may allow data to be stored in the variable resistance element VR.

Referring to FIG. 4, the variable resistance element VR may include a free layer FL, a pinned layer PL, and a tunnel layer TL. For example, the free layer FL, the pinned layer PL, and the tunnel layer TL may be disposed between the first bit line BL1 and the cell transistor CT. The tunnel layer TL may be disposed between the free layer FL and the pinned layer PL.

Referring to FIG. 5, a magnetization direction of the pinned layer PL may be fixed. A magnetization direction of the free layer FL may be the same direction as or a reverse direction to the magnetization direction of the pinned layer PL based on the bias condition.

When the magnetization direction of the free layer FL and the magnetization direction of the pinned layer PL are parallel to each other (e.g., has the same direction), the resistance value of the variable resistance element VR may be reduced. When the magnetization direction of the free layer FL and the magnetization direction of the pinned layer PL are anti-parallel with each other, the resistance value of the variable resistance element VR may increase.

For example, when a current flows from the free layer FL to the pinned layer PL, electrons may migrate from the pinned layer to the free layer FL. Electrons flowing through the pinned layer PL may spin in the magnetization direction of the pinned layer PL, and the free layer FL may be magnetized by electrons spinning in the magnetization direction of the pinned layer PL. For example, the free layer FL may be magnetized in the same direction as the magnetization direction of the pinned layer PL.

For example, when a current flows from the pinned layer PL to the free layer FL, electrons may migrate from the free layer FL to the pinned layer PL. Some of the electrons injected into the pinned layer PL may be reflected from the pinned layer PL to the free layer FL. The reflected electrons may spin in the magnetization direction of the pinned layer PL. The spinning direction of the reflected electrons may be opposite to the magnetization direction of the pinned layer PL. The free layer FL may be magnetized by the spinning electrons. That is, the free layer FL may be magnetized in a direction opposite to the magnetization direction of the pinned layer PL.

The variable resistance element VR′ may include a pinned layer PL′, a free layer FL′, and a tunnel layer TL′. Unlike the variable resistance element VR, each of the pinned layer PL′ and the free layer FL′ of the variable resistance element VR′ may have a magnetization direction in a vertical direction.

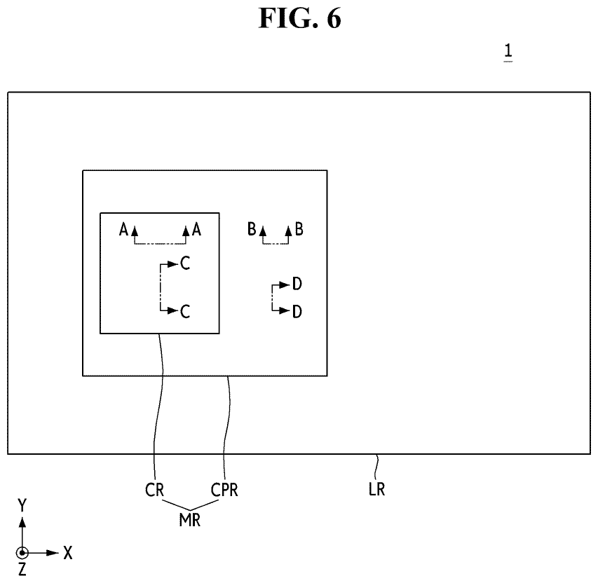

Hereinafter, the magnetic memory device 1 according to some embodiments will be described with reference to FIGS. 6 to 8.

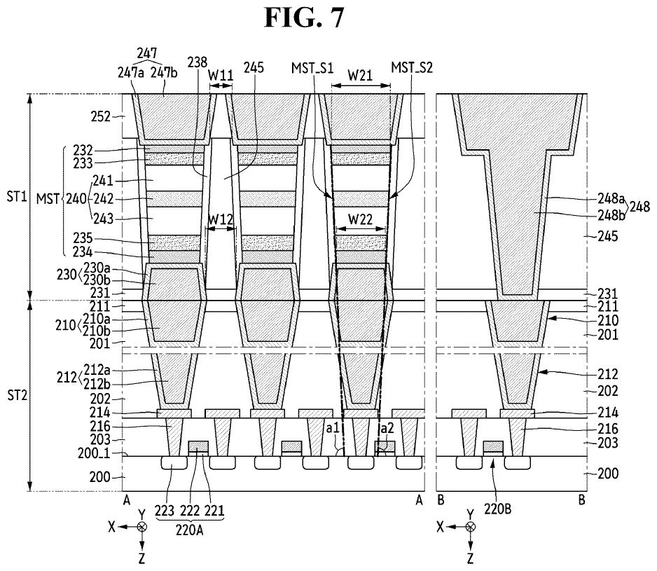

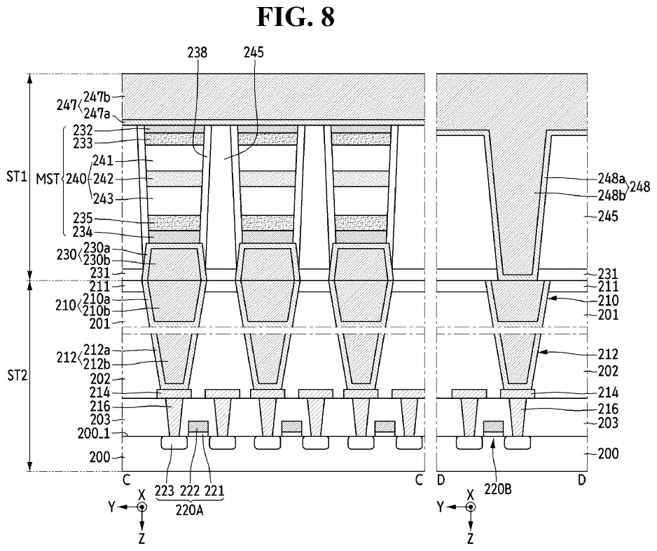

FIG. 6 is a plan view of a magnetic memory device according to some embodiments. FIG. 7 is a cross-sectional view of a magnetic memory device taken along lines A-A and B-B of FIG. 6. FIG. 8 is a cross-sectional view of the magnetic memory device taken along lines C-C and D-D of FIG. 6.

Referring to FIG. 6, the magnetic memory device 1 may include a memory area MR and a logic area LR. As described with reference to FIGS. 1 to 5, the memory area MR may include the controller 21 and the nonvolatile memory 100, and the logic area LR may include the host 10. The memory area MR may be embedded in the magnetic memory device 1, and in this case, the memory area MR may be an embedded MRAM (eMRAM).

The memory area MR and the logic area LR may be embedded in the magnetic memory device 1. Referring to FIG. 6, the memory area MR may be surrounded with the logic area LR. However, embodiments of the inventive concept are not limited thereto. The memory area MR may include a cell area CR and a core peripheral area CPR. The cell area CR may be surrounded with the core peripheral area CPR. However, embodiments of the present disclosure are not limited thereto.

The cell area CR may correspond to the memory cell array 110 of FIG. 2, and the core peripheral area CPR may correspond to the address decoder 120, the voltage generator 130, the read write circuit 140, the control logic 150, etc. The cell area CR may include the memory cell array 110 including the memory cell MC, and the core peripheral area CPR may include a circuit area around the memory cell array 110. In this regard, the cell area CR is illustrated as not overlapping the core peripheral area CPR. However, embodiments of the present disclosure are not limited thereto. For example, the core peripheral area CPR may overlap the cell area CR.

Referring to FIGS. 7 and 8, the magnetic memory device according to some embodiments may include a substrate 200, a first transistor 220A, a second transistor 220B, a lower insulating film 203, a contact pattern 216, a lower wiring structure 212 and 214, a first interlayer insulating film 202, a second interlayer insulating film 201, a second bonding pad 210, a second bonding insulating layer 211, a first bonding pad 230, a first bonding insulating layer 231, a memory structure MST, a capping insulating film 238, a mold insulating film 245, an etch stop film 252, a cell upper wiring 247, and a via structure 248.

In some embodiments, a first semiconductor structure ST1 may include the first bonding pad 230, the first bonding insulating layer 231, the memory structure MST, the capping insulating film 238, the mold insulating film 245, the etch stop film 252, the cell upper wiring 247, and the via structure 248. The second semiconductor structure ST2 may include the substrate 200, the first transistor 220A, the second transistor 220B, the lower insulating film 203, the contact pattern 216, the lower wiring structure 212 and 214, the first interlayer insulating film 202, the second interlayer insulating film 201, the second bonding pad 210, and the second bonding insulating layer 211.

The substrate 200 may be made of bulk silicon or silicon-on-insulator (SOI). Alternatively, the substrate 200 may be a silicon substrate, or may include a material other than silicon, such as silicon germanium, silicon germanium on insulator (SGOI), indium antimonide, lead telluride compound, indium arsenide, indium phosphide, gallium arsenide, or gallium antimonide. Alternatively, the substrate 200 may be formed by forming an epitaxial layer disposed on a base substrate. For example, in following descriptions, an example in which the substrate 200 is embodied as a silicon substrate will be described.

The substrate 200 may include a cell area CR and a core peripheral area CPR. The cell area CR and the core peripheral area CPR may be connected to each other or may be spaced apart from each other.

In some embodiments, the substrate 200 may extend in a first direction X and a second direction Y which perpendicularly intersect each other. Each of the first direction X and the second direction Y may mean a horizontal direction parallel to an upper surface 200_1 of the substrate. A third direction Z may mean a height direction perpendicular to each of the first direction X and the second direction Y. The third direction Z may mean a direction perpendicular to the upper surface 200_1 of the substrate.

The first semiconductor structure ST1 may be stacked on top of the second semiconductor structure ST2 in the third direction Z. The first semiconductor structure ST1 and the second semiconductor structure ST2 may be hybrid-bonded to each other via bonding of the first bonding pad 230 and the second bonding pad 210 and bonding of the first bonding insulating layer 231 and the second bonding insulating layer 211.

The first transistor 220A may be disposed in the cell area CR of the substrate 200. The second transistor 220B may be disposed in the core peripheral area CPR of the substrate 200. Each of the first transistor 220A and the second transistor 220B may include a MOS field effect transistor. For example, the first transistor 220A may include a gate dielectric film 221, a gate electrode 222, and source/drain areas 223. The source/drain areas 223 may be disposed on both opposing sides of the gate electrode 222, respectively. The gate dielectric film 221 may be interposed between the substrate 200 and the gate electrode 222.

Although each of the first transistor 220A and the second transistor 220B is shown as a planar field effect transistor, this is only an example. Unlike the illustrated example, each of the first transistor 220A and the second transistor 220B may include a fin type field effect transistor (FinFET) including a fin-shaped channel, a field effect transistor including a nanowire or nanosheet-shaped channel, a MBCFET® including a multi-bridge channel, a vertical FET (VFET), a complementary FET (CFET), or a three-dimensional (3D) transistor, etc.

In some embodiments, the first transistor 220A and the second transistor 220B may be disposed at the same level. As used herein, the term “A and B being disposed in the same level” means that A and B are formed in the same manufacturing process.

For example, the gate electrode 222 of the first transistor 220A may be provided as a word line (WL of FIG. 2) of the magnetic memory device, and may be configured to selectively control the memory cell (MC of FIG. 3) connected to the first transistor 220A. However, embodiments of the present disclosure are not limited thereto.

The lower insulating film 203 may be disposed on the cell area CR and the core peripheral area CPR. The lower insulating film 203 may cover the first transistor 220A and the second transistor 220B. The lower insulating film 203 may include, for example, at least one of silicon oxide, silicon nitride, silicon oxynitride, silicon oxycarbide, silicon boron nitride, silicon boron carbonitride, silicon oxycarbonitride, a low-k material having a dielectric constant lower than silicon oxide, or a combination thereof. However, embodiments of the present disclosure are not limited thereto. The low-k material may include at least one of, for example, FOX (Flowable Oxide), TOSZ (Tonene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and combinations thereof. However, embodiments of the present disclosure are not limited thereto.

The contact pattern 216 may be disposed in the lower insulating film 203. The contact pattern 216 may be electrically connected to the first transistor 220A and/or the second transistor 220B. For example, the contact pattern 216 may contact the source/drain areas 223 and/or the gate electrode 222.

The contact pattern 216 may include, for example, a conductive metal (e.g., titanium, tantalum, ruthenium, or tungsten) or a conductive metal nitride (e.g., titanium nitride or tantalum nitride). However, embodiments of the present disclosure are not limited thereto.

The first interlayer insulating film 202 may be disposed on the lower insulating film 203. The first interlayer insulating film 202 may include, for example, at least one of silicon oxide, silicon nitride, silicon oxynitride, silicon oxycarbide, silicon boron nitride, silicon boron carbonitride, silicon oxycarbonitride, a low-k material having a dielectric constant lower than that of silicon oxide, or a combination thereof. However, embodiments of the present disclosure are not limited thereto.

The lower wiring structure 212 and 214 may be disposed in the first interlayer insulating film 202. The lower wiring structure 212 and 214 may be electrically connected to the first transistor 220A and/or the second transistor 220B via the contact pattern 216. The lower wiring structure 212 and 214 may include multi-layered lower wiring patterns 214 and lower via patterns 212 connecting the lower wiring patterns 214 and the second bonding pads 210 to each other. The number of layers, the number, and the arrangement of the lower wiring patterns 214 and the lower via patterns 212 are only examples, and are not limited to those illustrated.

In some embodiments, the multi-layered lower wiring patterns 214 may be connected to one of the source/drain areas 223 via the contact pattern 216.

In some embodiments, each of the lower via patterns 212 may include a barrier pattern 212a and a conductive pattern 212b. The barrier pattern 212a may be formed to surround a sidewall and a bottom surface of the conductive pattern 212b. The barrier pattern 212a may include, for example, a metal nitride such as tungsten nitride, tantalum nitride, titanium nitride, or the like, and/or a metal such as tantalum, titanium, etc. The conductive pattern 212b may include copper.

The lower wiring patterns 214 may include, for example, a conductive metal (e.g., titanium, tantalum, ruthenium, or tungsten) or a conductive metal nitride (e.g., titanium nitride or tantalum nitride). However, embodiments of the present disclosure are not limited thereto.

The second interlayer insulating film 201 may be disposed on the first interlayer insulating film 202. The second interlayer insulating film 201 may include, for example, at least one of silicon oxide, silicon nitride, silicon oxynitride, silicon oxycarbide, silicon boron nitride, silicon boron carbonitride, silicon oxycarbonitride, a low-k material having a dielectric constant lower than that of silicon oxide, or a combination thereof. However, embodiments of the present disclosure are not limited thereto.

The second bonding pad 210 may be disposed on the cell area CR and the core peripheral area CPR. The second bonding pad 210 may be disposed in the second bonding insulating layer 211 and the second interlayer insulating film 201. The second bonding pad 210 may extend through the second bonding insulating layer 211 and the second interlayer insulating film 201 so as to contact the lower via patterns 212.

In some embodiments, the second bonding pad 210 may include a barrier pattern 210a and a conductive pattern 210b. The barrier pattern 210a may be formed to surround a sidewall and a bottom surface of the conductive pattern 210b. The barrier pattern 210a may include, for example, a metal nitride such as tungsten nitride, tantalum nitride, titanium nitride, or the like, and/or a metal such as tantalum, titanium, etc. The conductive pattern 210b may include copper.

The second bonding insulating layer 211 may be disposed on the second interlayer insulating film 201. The second bonding insulating layer 211 may conformally extend along an upper surface of the second interlayer insulating film 201. The second bonding insulating layer 211 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AlO), or a combination thereof. However, embodiments of the present disclosure are not limited thereto.

The first bonding pad 230 may be disposed on the cell area CR. The first bonding pad 230 may be disposed in the first bonding insulating layer 231. The first bonding pad 230 may extend through the first bonding insulating layer 231 so as to contact the memory structure MST. The first bonding pad 230 may be electrically connected to the first transistor 220A via the second bonding pad 210, the lower wiring structure 212 and 214, and the contact pattern 216. The memory structure MST may be electrically connected to the first transistor 220A via the first bonding pad 230, the second bonding pad 210, the lower wiring structure 212 and 214, and the contact pattern 216.

In some embodiments, the first bonding pad 230 may include a barrier pattern 230a and a conductive pattern 230b. The barrier pattern 230a may be formed to surround a sidewall and a bottom surface of the conductive pattern 230b. The barrier pattern 230a may include, for example, a metal nitride such as tungsten nitride, tantalum nitride, titanium nitride, or the like, and/or a metal such as tantalum, titanium, etc. The conductive pattern 230b may include copper.

The first bonding insulating layer 231 may be disposed on the second bonding insulating layer 211. The first bonding insulating layer 231 may conformally extend along an upper surface of the second bonding insulating layer 211. The first bonding insulating layer 231 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AlO), or a combination thereof. However, embodiments of the present disclosure are not limited thereto.

A plurality of memory structures MST may be disposed on the second interlayer insulating film 201 of the cell area CR. The plurality of memory structures MST may be arranged to be spaced apart from each other in each of the first direction X and the second direction Y parallel to the upper surface 200_1 of the substrate 200. Each of the plurality of memory structures MST may include a second electrode layer 234, a second barrier layer 235, a magnetic tunnel junction layer 240, a first barrier layer 233, and a first electrode layer 232, which are sequentially stacked. The magnetic tunnel junction layer 240 may be disposed between the second electrode layer 234 and the first electrode layer 232.

The second electrode layer 234 may be disposed on the first bonding pad 230. The second electrode layer 234 may be disposed, for example, between the first bonding pad 230 and the magnetic tunnel junction layer 240. The second electrode layer 234 may include, for example, a conductive metal (e.g., titanium, tantalum, ruthenium, or tungsten) or a conductive metal nitride (e.g., titanium nitride or tantalum nitride). However, embodiments of the present disclosure are not limited thereto.

The second barrier layer 235 may be disposed between the second electrode layer 234 and the magnetic tunnel junction layer 240. The second barrier layer 235 may include at least one of a metal and a metal oxide. For example, the second barrier layer 235 may include a conductive metal (e.g., titanium, tantalum, ruthenium, or tungsten). Alternatively, for example, the second barrier layer 235 may include an oxide of a conductive metal included in the second electrode layer 234 or an oxide of a conductive metal nitride included in the second electrode layer 234.

For example, the second barrier layer 235 may serve as a crystalline conserving layer for preventing crystallinity resulting from the second electrode layer 234 disposed under the second barrier layer 235.

The magnetic tunnel junction layer 240 may include a second magnetic pattern 243, a tunnel barrier pattern 242, and a first magnetic pattern 241, which are sequentially stacked. The tunnel barrier pattern 242 may be disposed between the second magnetic pattern 243 and the first magnetic pattern 241.

In some embodiments, each of the second magnetic pattern 243 and the first magnetic pattern 241 may have perpendicular magnetic anisotropy (PMA). For example, each of the second magnetic pattern 243 and the first magnetic pattern 241 may include at least one of an intrinsic perpendicular magnetic material and an extrinsic perpendicular magnetic material. For example, each of the second magnetic pattern 243 and the first magnetic pattern 241 may have a magnetization easy axis in a vertical direction (e.g., the third direction Z or DR.3).

The intrinsic perpendicular magnetic material may refer to a material having perpendicular magnetization ability even when there is no external factor. For example, the intrinsic perpendicular magnetic material may include at least one of i) a perpendicular magnetic material (e.g., CoFeTb, CoFeGd, and CoFeDy), ii) a perpendicular magnetic material having a L1₀ structure, iii) a CoPt having a hexagonal close packed lattice structure, and iv) a perpendicular magnetic structure. The perpendicular magnetic material having the L1₀ structure may include, for example, FePt having a L1₀ structure, FePd having a L1₀ structure, CoPd having a L1₀ structure, CoPt having a L1₀ structure, etc. The perpendicular magnetic structure may include magnetic layers and non-magnetic layers that are alternately and repeatedly stacked on top of each other. For example, the perpendicular magnetic structure may include (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ or (CoCr/Pd)ₙ (where n is the number of stacks).

The extrinsic perpendicular magnetic material may refer to a material having an intrinsic in-plane magnetization property but having a perpendicular magnetization property due to an external factor. For example, the extrinsic perpendicular magnetic material may have perpendicular magnetic anisotropy (i.e., interfacial perpendicular magnetic anisotropy (i-PMA)) induced via a junction thereof with the tunnel barrier pattern 242. The extrinsic perpendicular magnetic material may include, for example, CoFeB or CoFe. However, embodiments of the present disclosure are not limited thereto.

In some embodiments, each of the second magnetic pattern 243 and the first magnetic pattern 241 may have in-plane magnetic anisotropy (IMA). For example, each of the second magnetic pattern 243 and the first magnetic pattern 241 may have a magnetization easy axis in a horizontal direction (e.g., the first direction X or the second direction Y).

Each of the second magnetic pattern 243 and the first magnetic pattern 241 having the IMA may include a ferromagnetic material. In some embodiments, a magnetic pattern constituting a reference layer among the second magnetic pattern 243 and the first magnetic pattern 241 may further include an antiferromagnetic material for fixing the magnetization direction of the ferromagnetic material. In some embodiments, each of the second magnetic pattern 243 and the first magnetic pattern 241 may include a Co-based Heusler alloy.

The tunnel barrier pattern 242 may be provided as an insulated tunnel barrier that generates quantum mechanical tunneling between the second magnetic pattern 243 and the first magnetic pattern 241. The tunnel barrier pattern 242 may include, for example, at least one of magnesium (Mg) oxide, aluminum (Al) oxide, magnesium-zinc (Mg—Zn) oxide, magnesium-boron (Mg—B) oxide, silicon (Si) oxide, tantalum (Ta) oxide, silicon nitride (SiN), aluminum nitride (AlN), or a combination thereof. However, embodiments of the present disclosure are not limited thereto. For example, the tunnel barrier pattern 242 may include a magnesium oxide (MgO) film having a face-centered cubic (FCC) crystal structure or a sodium chloride (NaCl) crystal structure.

The magnetic tunnel junction layer 240 may store data in each of the memory cells MC using a difference in electrical resistance based on the magnetization direction of the second magnetic pattern 243 and the magnetization direction of the first magnetic pattern 241. In some embodiments, the magnetic tunnel junction layer 240 may be provided as a variable resistance element that may be switched to two resistance states based on an electrical signal (e.g., a program current) applied thereto. For example, when the magnetization direction of the second magnetic pattern 243 and the magnetization direction of the first magnetic pattern 241 are parallel to each other, the magnetic tunnel junction layer 240 may have a low resistance value and store the low resistance value as data ‘0’. On the contrary, when the magnetization direction of the second magnetic pattern 243 and the magnetization direction of the first magnetic pattern 241 are antiparallel to each other, the magnetic tunnel junction layer 240 may have a high resistance value and store the high resistance value as data ‘1’.

The first electrode layer 232 may be disposed between the magnetic tunnel junction layer 240 and the cell upper wiring 247. The first electrode layer 232 may include, for example, a conductive metal (e.g., titanium, tantalum, ruthenium, or tungsten) or a conductive metal nitride (e.g., titanium nitride or tantalum nitride). However, embodiments of the present disclosure are not limited thereto.

The first barrier layer 233 may be disposed between the first electrode layer 232 and the magnetic tunnel junction layer 240. The first barrier layer 233 may include at least one of a metal and a metal oxide. For example, the first barrier layer 233 may include a conductive metal (e.g., titanium, tantalum, ruthenium, or tungsten). Alternatively, for example, the first barrier layer 233 may include an oxide of the conductive metal included in the first electrode layer 232 or an oxide of the conductive metal nitride included in the first electrode layer 232.

For example, the first barrier layer 233 may serve as a crystalline conserving layer. Alternatively, in another example, the first barrier layer 233 may serve as an antioxidant layer for preventing oxidation of the first magnetic pattern 241.

For example, the second electrode layer 234 and the first electrode layer 232 may include different metal materials. In this case, the second electrode layer 234 may include tantalum nitride (TaN), and the first electrode layer 232 may include titanium nitride (TiN). However, embodiments of the present disclosure are not limited thereto. Alternatively, in another example, the second electrode layer 234 and the first electrode layer 232 may include the same metal material.

When the second electrode layer 234 and the first electrode layer 232 include different metal materials, the second barrier layer 235 and the first barrier layer 233 may also include different metal materials.

The capping insulating film 238 may be disposed on the first bonding insulating layer 231 in the cell area CR. The capping insulating film 238 may be conformally formed on a side surface of each of the plurality of memory structures MST. The capping insulating film 238 may conformally cover a side surface of each of the second electrode layer 234, the second barrier layer 235, the magnetic tunnel junction layer 240, the first barrier layer 233, and the first electrode layer 232. The capping insulating film 238 may include a nitride (e.g., silicon nitride). However, embodiments of the present disclosure are not limited thereto.

The mold insulating film 245 may be formed on an upper surface of the capping insulating film 238. The mold insulating film 245 may fill a space between adjacent ones of the plurality of memory structures MST. The mold insulating film 245 may include, for example, at least one of silicon oxide, silicon nitride, silicon oxynitride, silicon oxycarbide, silicon boron nitride, silicon boron carbonitride, silicon oxycarbonitride, a low-k material having a dielectric constant lower than that of silicon oxide, or a combination thereof. However, embodiments of the present disclosure are not limited thereto.

The etch stop film 252 may be disposed on the mold insulating film 245. The etch stop film 252 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AlO), or a combination thereof. However, embodiments of the present disclosure are not limited thereto.

The cell upper wiring 247 may be disposed on the cell area CR. The cell upper wiring 247 may be disposed on the memory structure MST. The cell upper wiring 247 may be in direct contact with the first electrode layer 232. For example, the cell upper wiring 247 may extend through the etch stop film 252 so as to contact the first electrode layer 232. For example, the cell upper wiring 247 may be provided as the bit line (BL of FIG. 2) of the magnetic memory device.

The cell upper wiring 247 may include a barrier pattern 247a and a conductive pattern 247b. The barrier pattern 247a may be formed to surround a sidewall and a bottom surface of the conductive pattern 247b. The barrier pattern 247a may include, for example, a metal nitride such as tungsten nitride, tantalum nitride, titanium nitride, or the like, and/or a metal such as tantalum, titanium, etc. The conductive pattern 247b may include copper.

A sidewall of the via structure 248 may be surrounded with the mold insulating film 245. The via structure 248 may include a peripheral upper contact and a peripheral upper wiring disposed on the peripheral upper contact. A width of the peripheral upper wiring may be greater than a width of the peripheral upper contact. The peripheral upper contact may extend through the mold insulating film 245 so as to may be electrically connected to the second bonding pad 210. The peripheral upper contact may be electrically connected to the lower via patterns 212 via the second bonding pad 210. The via structure 248 may be electrically connected to the second transistor 220B via the second bonding pad 210 and the lower wiring structure 212 and 214.

The via structure 248 may include a barrier pattern 248a and a conductive pattern 248b. The barrier pattern 248a may be formed to surround a sidewall and a bottom surface of the conductive pattern 248b. The barrier pattern 248a may include, for example, a metal nitride such as tungsten nitride, tantalum nitride, titanium nitride, or the like, and/or a metal such as tantalum, titanium, etc. The conductive pattern 248b may include copper.

The mold insulating film 245 may include a first area AR1 adjacent to the cell upper wiring 247 and a second area AR2 adjacent to the second bonding pad 230. In the first direction X, a width W12 of the second area II may be greater than a width W11 of the first area II. In the second direction Y, a width of the second area II may be greater than a width of the first area II.

The memory structure MST may include a third area adjacent to the cell upper wiring 247 and a fourth area adjacent to the second bonding pad 230. In the first direction X, a width W22 of the fourth area AR4 may be smaller than a width W21 of the third area AR3. In the second direction Y, a width of the fourth area AR4 may be smaller than a width of the third area AR3.

The memory structure MST may include a first sidewall MST_S1 and a second sidewall MST_S2 facing each other. Each of the first sidewall MST_S1 and the second sidewall MST_S2 may be inclined with respect to the upper surface 200_1 of the substrate 200. For example, the first sidewall MST_S1 may define an acute angle a1 in the counterclockwise direction with respect to the upper surface 200_1 of the substrate 200. The second sidewall MST_S2 may define an acute angle a2 in the clockwise direction with respect to the upper surface 200_1 of the substrate 200.

That is, the width of the memory structure MST may decrease as the memory structure MST extends toward the upper surface 200_1 of the substrate 200. The width of the mold insulating film 245 may increase as the mold insulating film extends toward the upper surface 200_1 of the substrate 200.

Each of the width in the first direction X of the cell upper wiring 247 and the width in the first direction X of the first bonding pad 230 may decrease as each of the cell upper wiring 247 and the first bonding pad 230 extends toward the magnetic tunnel junction layer 240. The width of the first bonding pad 230 in the second direction Y may decrease as the first bonding pad 230 extends toward the magnetic tunnel junction layer 240.

In the first direction X and/or the second direction Y, the width of the first bonding pad 230 may increase as the first bonding pad 230 extends toward the upper surface 200_1 of the substrate 200. In the first direction X and/or the second direction Y, the width of the second bonding pad 210 may decrease as the second bonding pad 210 extends toward the upper surface 200_1 of the substrate 200.

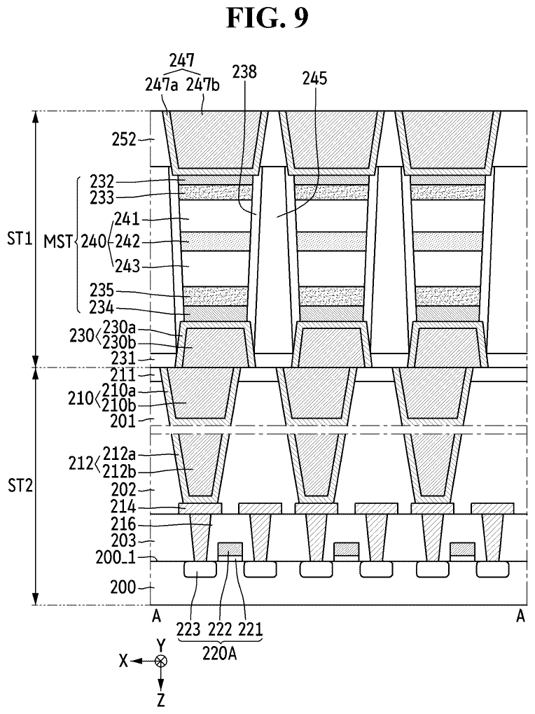

FIG. 9 is a diagram for illustrating a magnetic memory device according to some embodiments, and corresponds to FIG. 7. For convenience of description, differences between FIG. 7 and FIG. 9 will be mainly described.

Referring to FIG. 9, the first bonding pad 230 may not be aligned with the second bonding pad 210 in the third direction Z. The first bonding pad 230 may be positioned to be misaligned with the second bonding pad 210 in the third direction Z. In the third direction Z, only a portion of the first bonding pad 230 may overlap the second bonding pad 210, that is, the first bonding pad 230 may not entirely overlap the second bonding pad 210

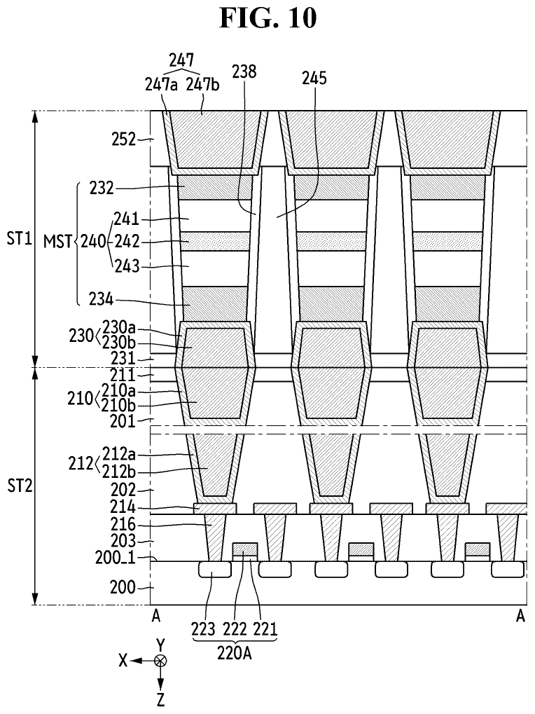

FIG. 10 is a diagram for illustrating a magnetic memory device according to some embodiments, and corresponds to FIG. 7. For convenience of description, differences between FIG. 10 and FIGS. 7 to 9 will be mainly described.

Referring to FIG. 10, the memory structure MST may not include the second barrier layer 235 (see FIG. 7) between the second electrode layer 234 and the magnetic tunnel junction layer 240, and the first barrier layer 233 (see FIG. 7) between the first electrode layer 232 and the magnetic tunnel junction layer 240. The second electrode layer 234 may be in direct contact with the second magnetic pattern 243, and the first electrode layer 232 may be in direct contact with the first magnetic pattern 241.

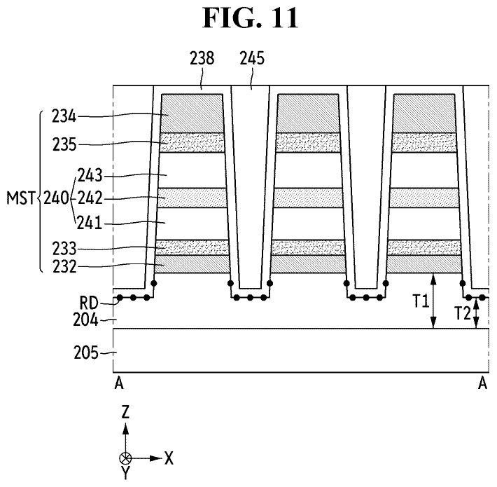

FIGS. 11 to 17 are diagrams of intermediate structures corresponding to intermediate steps of a method for manufacturing a magnetic memory device according to some embodiments. For convenience, in the descriptions of FIGS. 11 to 17, descriptions duplicate with those set forth above with reference to FIGS. 7 and 8 will be omitted.

Referring to FIG. 11, a buffer insulating film 204 is provided on a sacrificial substrate 205. The sacrificial substrate 205 may include silicon (Si). The buffer insulating film 204 may include silicon oxide.

A pre-first electrode layer, a pre-first barrier layer, a pre-magnetic tunnel junction layer, a pre-second barrier layer, and a pre-second electrode layer which are sequentially stacked in the third direction Z may be formed on the buffer insulating film 204. Each of the first electrode layer, the pre-first barrier layer, the pre-magnetic tunnel junction layer, the pre-second barrier layer, and the pre-second electrode layer may extend parallel to the upper surface of the buffer insulating film 204. Thereafter, the memory structure MST may be formed by patterning at least a portion of the buffer insulating film 204, the pre-first electrode layer, the pre-first barrier layer, the pre-magnetic tunnel junction layer, the pre-second barrier layer, and the pre-second electrode layer.

The memory structure MST may include the first electrode layer 232, the first barrier layer 233, the magnetic tunnel junction layer 240, the second barrier layer 235, and the second electrode layer 234, which are sequentially stacked in the third direction Z. The capping insulating layer 238 may be formed on the memory structures MST. The capping insulating film 238 may conformally cover a side surface of each of the first electrode layer 232, the first barrier layer 233, the magnetic tunnel junction layer 240, the second barrier layer 235, and the second electrode layer 234. After the capping insulating layer 238 has been formed, the mold insulating film 245 may be formed between the memory structures MST.

A thickness of a portion of the capping insulating layer 238 formed on the upper surface of the memory structure MST may be greater than a thickness of a portion of the capping insulating layer 238 formed on the sidewall of the memory structure MST. For example, the thickness of the portion of the capping insulating film 238 formed on the upper surface of the memory structure MST may be 120 angstroms, and the thickness of the portion of the capping insulating film 238 formed on the sidewall of the memory structure MST may be 80 angstroms. However, embodiments of the present disclosures are not limited thereto.

In the patterning process for forming the memory structure MST, an upper surface of the buffer insulating film 204 may be recessed. A recess depth of the buffer insulating film 204 may be variously adjusted. For example, the recess depth of the buffer insulating film 204 may be set such that a vertical level of a bottom surface of the recess is lower than that of the upper surface of the buffer insulating film 204 in contact with the first electrode layer 232. In this case, a thickness T2 of the buffer insulating film 204 in a recess area may be smaller than a thickness T1 of the buffer insulating film 204 in an area in contact with the first electrode layer 232.

A re-deposition material RD may include conductive by-products generated (e.g., from the second electrode layer 234) in the patterning process for forming the memory structure MST. The re-deposition material RD may be formed in the recess area of the buffer insulating film 204. For example, the re-deposition material RD may include a conductive metal (e.g., titanium, tantalum, ruthenium, or tungsten) or a conductive metal nitride (e.g., titanium nitride or tantalum nitride). However, embodiments of the present disclosure are not limited thereto.

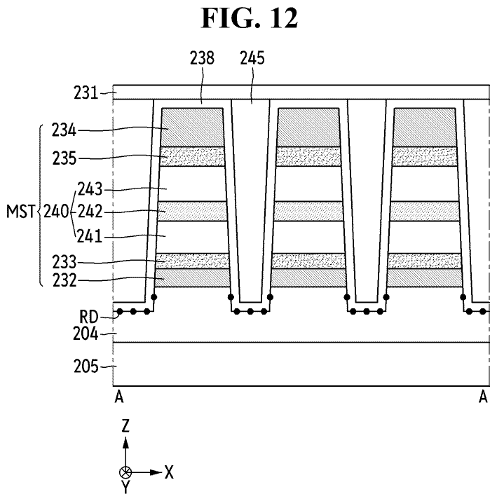

Referring to FIG. 12, the first etch stop film 231 may be formed on the memory structure MST. The first etch stop film 231 may be formed on a upper surface of the mold insulating film 245 and a upper surface of the capping insulating layer 238 covering the memory structure MST. The first etch stop film 231 may be formed on the second electrode layer 234. The first etch stop film 231 may include, for example, silicon carbonitride (SiCN). However, embodiments of the present disclosure are not limited thereto.

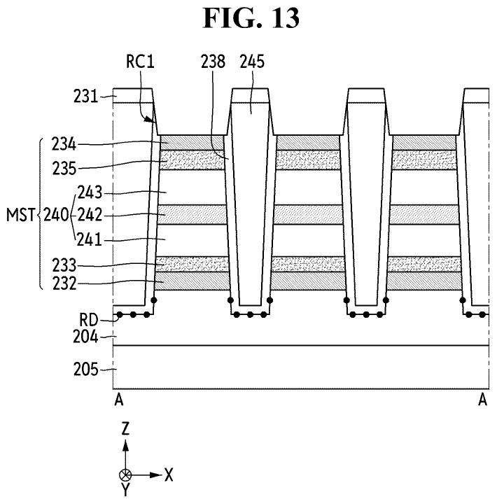

Referring to FIG. 13, the first etch stop film 231 and at least a portion of the memory structure MST may be removed to form a first recess RC1 in the memory structure MST. The first recess RC1 may be formed in the first etch stop film 231 and the second electrode layer 234. The first recess RC1 may expose a sidewall of the first etch stop film 231 and an upper surface of the second electrode layer 234.

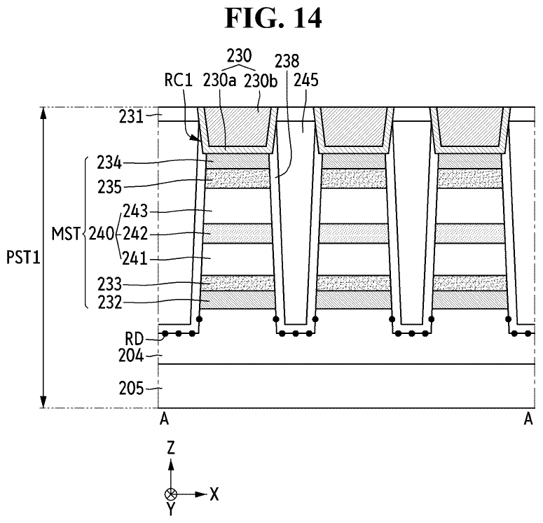

Referring to FIG. 14, the first bonding pad 230 may be formed in the first recess RC1. The first bonding pad 230 may include a barrier pattern 230a on a sidewall and a bottom surface of the first recess RC1 and a conductive pattern 230b on the barrier pattern 230a. A width of the first recess RC1 may decrease as the first recess RC1 extends toward the memory structure MST. The width of the first bonding pad 230 may decrease as the first bonding pad 230 extends toward the memory structure MST. Accordingly, a pre-first semiconductor structure PST1 may be formed.

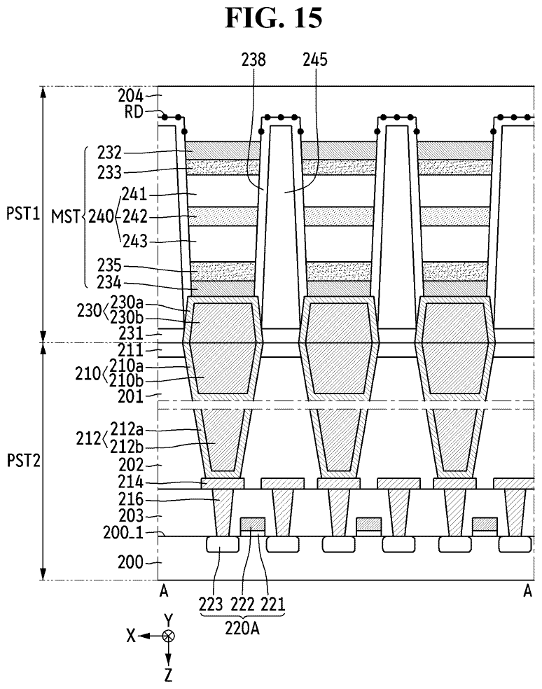

Referring to FIG. 15, the substrate 200 on which the first transistor 220A has been formed is provided. The first transistor 220A may include the gate dielectric film 221, the gate electrode 222, and the source/drain areas 223. The lower insulating film 203 and the first interlayer insulating film 202 may be formed on the substrate 200. The contact pattern 216 connected to the transistor 220A and the lower wiring structure 212 and 214 connected thereto may be formed in the lower insulating film 203 and the first interlayer insulating film 202. The second interlayer insulating film 201 and the second bonding insulating layer 211 may be formed on the first interlayer insulating film 202. The second bonding pad 210 connected to the lower wiring structure 212 and 214 may be formed in the second interlayer insulating film 201 and the second bonding insulating layer 211. Accordingly, a pre-second semiconductor structure PST2 may be formed.

Thereafter, the sacrificial substrate (205 of FIG. 14) may be removed, and the memory structure MST of FIG. 14 may be turned upside down. The first bonding pad 230 and the second bonding pad 210 may face each other to bond the first bonding pad 230 and the second bonding pad 210 to each other. Accordingly, the pre-first semiconductor structure PST1 may be stacked on the pre-second semiconductor structure PST2.

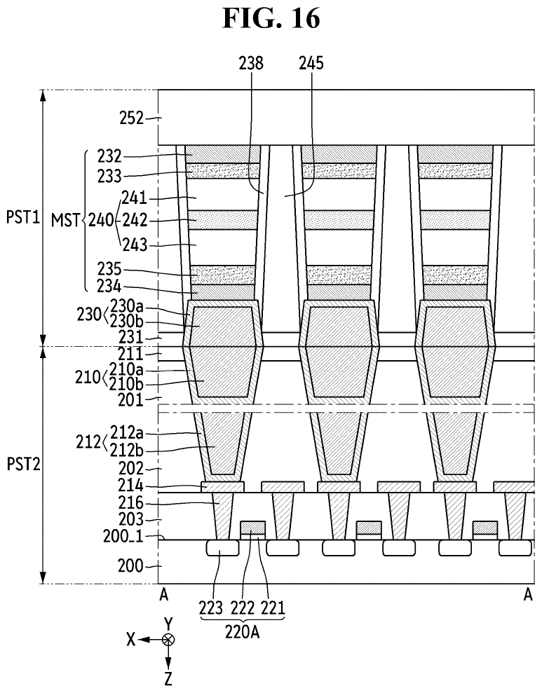

Referring to FIG. 16, a planarization process may be performed on the pre-first semiconductor structure PST1 such that one surface of the mold insulating film 245, one surface of the first electrode layer 232, and one surface of the capping insulating film 238 are coplanar with each other. For example, the planarization process may be chemical mechanical polishing (CMP). However, embodiments of the present disclosure are not limited thereto.

The buffer insulating film 204, a portion of the mold insulating film 245, and a portion of the capping insulating layer 238 may be removed. Node isolation of the memory structure MST may be performed, and the re-deposition material RD (see FIG. 15) may be removed. As the re-deposition material RD (see FIG. 15) has been removed, the performance and reliability of the magnetic memory device may be improved.

The second etch stop film 252 may be formed on one surface of the mold insulating film 245, one surface of the first electrode layer 232, and one surface of the capping insulating layer 238. The second etch stop film 252 may include, for example, silicon carbonitride (SiCN). However, embodiments of the present disclosure are not limited thereto.

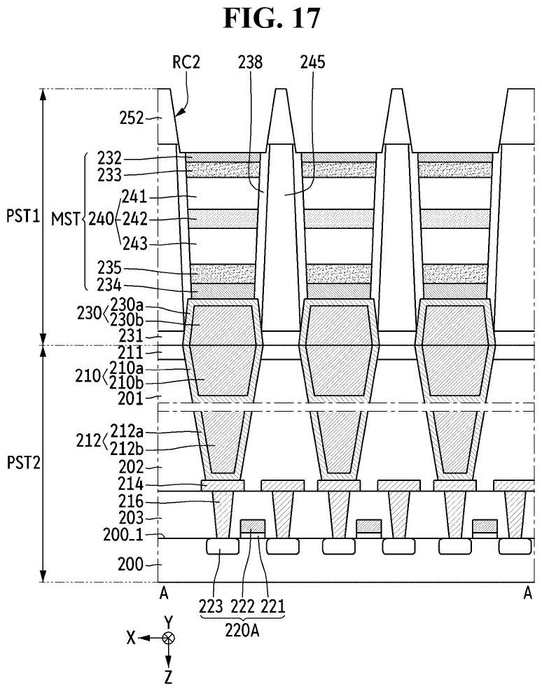

Referring to FIG. 17, the second etch stop film 252 and at least a portion of the memory structure MST may be removed to form a second recess RC2 in the memory structure MST. The second recess RC2 may be formed in the second etch stop film 252 and the first electrode layer 232. The second recess RC2 may expose a sidewall of the second etch stop film 252 and an upper surface of the first electrode layer 232.

Thereafter, the cell upper wiring 247 may be formed in the second recess RC 2. The cell upper wiring 247 may be provided as the bit line BL. Accordingly, the magnetic memory device as described with reference to FIG. 7 may be manufactured.

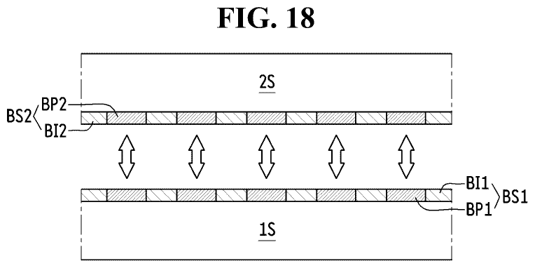

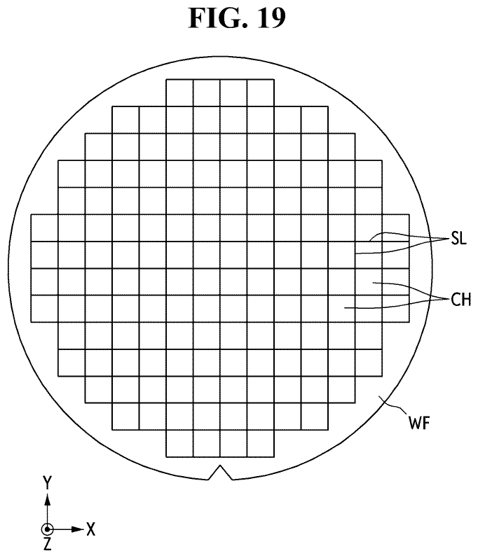

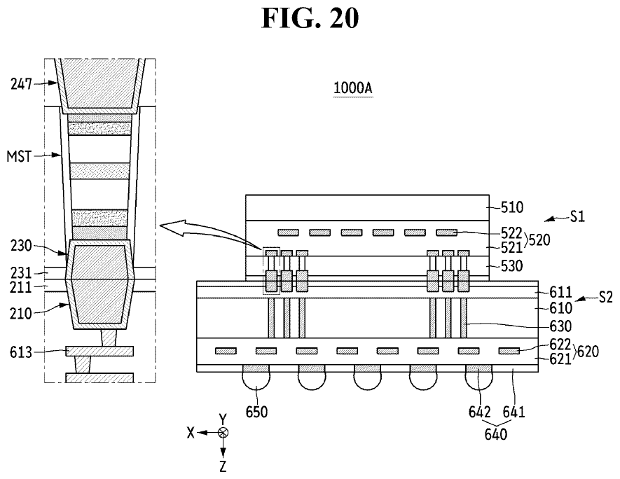

FIG. 18 is a view for illustrating bonding between adjacent ones of a plurality of semiconductor chips in a semiconductor structure according to some embodiments. FIG. 19 is a plan view illustrating a chip area and a scribe lane area of a semiconductor wafer. FIG. 20 is a cross-sectional view of a semiconductor structure according to some embodiments. For convenience, in description of FIGS. 18 to 20, descriptions duplicate with those as described with reference to FIGS. 7 to 17 will be omitted.

Referring to FIG. 18, a first structure 1S including a first bonding structure BS1 may be formed, a second structure 2S including a second bonding structure BS2 may be formed, and the first structure 1S and the second structure 2S may be bonded to each other such that the first bonding structure BS1 and the second bonding structure BS2 directly contact each other.

The first bonding structure BS1 may include a first bonding pad BP1 and a first bonding insulating layer BI1 surrounding at least a portion of a side surface of the first bonding pad BP1, and the second bonding structure BS2 may include a second bonding pad BP2 and a second bonding insulating layer BI2 surrounding at least a portion of a side surface of the second bonding pad BP2. The first bonding pad BP 1 and the second bonding pad BP 2 may be in contact with each other and may be bonded to each other via a copper (Cu)-copper (Cu) bonding manner. The first bonding insulating layer BI1 and the second bonding insulating layer BI2 may be in contact with each other and may be coupled by dielectric-to-dielectric bonding. Each of the first bonding structure BS1 and the second bonding structure BS2 may be electrically connected to a redistribution layer or a through-via disposed in each of the first structure 1S and the second structure 2S.

In an example embodiment, the bonding of the first structure 1S and the second structure 2S may be a die-to-die bonding or a die-to-wafer bonding. For example, when each of the first structure 1S and the second structure 2S is a semiconductor chip, the bonding of the first structure 1S and the second structure 2S may be a die-to-die bonding. For example, when the first structure 1S is one of a plurality of semiconductor structures distinguished from each other via a scribe lane on a semiconductor wafer, and the second structure 2S is a semiconductor chip disposed on top of each of the plurality of semiconductor structures, the bonding of the first structure 1S and the second structure 2S may be a die-to-wafer bonding. For example, when each of the first structure 1S and the second structure 2S is one of a plurality of semiconductor structures distinguished from each other via a scribe lane in each of the first semiconductor wafer and the second semiconductor wafer, the bonding of the first structure 1S and the second structure 2S may be a wafer-to-wafer bonding

Referring to FIG. 19, a semiconductor wafer WF including a plurality of chip areas CH and a plurality of scribe lane areas SL, each being disposed between adjacent ones of the plurality of chip areas CH, may be provided. The semiconductor wafer WF may be a semiconductor wafer before dicing is performed thereon. The plurality of scribe lane areas SL may include one area through which a dicing line DL passes. In this regard, the dicing line DL may be a virtual line. A dicing process to be described later may cut the semiconductor wafer WF along the dicing line DL. The semiconductor wafer WF may include a semiconductor substrate 510, a circuit layer 520, and an element layer 530 of FIG. 20.

Referring to FIG. 20, a semiconductor package 1000A according to some embodiments may include a first semiconductor chip S1, and may have a structure in which the first semiconductor chip S1 and the second semiconductor structure S2 are bonded to each other. The second semiconductor structure S2 may be a semiconductor chip.

The semiconductor package 1000A according to some embodiments may include the second semiconductor structure S2 and the first semiconductor chip S1 stacked in the vertical direction Z. The second semiconductor structure S2 and the first semiconductor chip S1 may be boned to each other such that elements not covered with an upper surface of the second semiconductor structure S2 and elements not covered with a lower surface of the first semiconductor chip S1 are directly bonded to each other (e.g. this bonding may mean hybrid bonding, direct bonding, or the like) without a separate connection member (e.g., a metal pillar, a solder bump, or the like). For example, a dielectric-to-dielectric bonding and a copper-to-copper bonding may be formed at an interface between the second semiconductor structure S2 and the first semiconductor chip S1. The second bonding structure 210 of the second semiconductor structure S2 and the first bonding structure 230 of the first semiconductor chip S1 may be bonded to each other to be coupled to each other.

The second semiconductor structure S2 as a semiconductor wafer-based structure may include a first semiconductor substrate 610, a back protective layer 611 and 211, a circuit layer 620, a through-via 630, and a front protective layer 640. For example, the second semiconductor structure S2 may be a silicon interposer substrate, a semiconductor chip, etc.

The first semiconductor substrate 610 may include a semiconductor element such as silicon or germanium, or a compound semiconductor such as silicon carbide (SiC), gallium arsenide (GaAs), indium arsenide (InAs), and indium phosphide (InP). The first semiconductor substrate 610 may be a portion of a semiconductor wafer, and may be provided as an individual semiconductor substrate 610 obtained by cutting the semiconductor wafer.

The circuit layer 620 may be disposed on a front surface of the first semiconductor substrate 610 and may include an interlayer insulating layer 621 and an inner wiring 622. The interlayer insulating layer 621 may include at least one of silicon oxide, silicon nitride, and silicon oxynitride. The inner wiring 622 may redistribute a front pad 642 disposed on the rear surface or the through-via 630, and may be formed in a multilayer structure including a plurality of wiring lines and a plurality of wiring vias. The wiring lines and the wiring vias may include, for example, a metal material including aluminum (Al), gold (Au), cobalt (Co), copper (Cu), nickel (Ni), lead (Pb), tantalum (Ta), tellurium (Te), titanium (Ti), tungsten (W), or a combination thereof. A barrier layer (not shown) including titanium (Ti), titanium nitride (TiN), tantalum (Ta), or tantalum nitride (TaN) may be disposed between the wiring line and/or the wiring via and the interlayer insulating layer 621.

The back protective layer 611 and 211 may be disposed on the rear surface of the first semiconductor substrate 610 and may include a back insulating layer 211 and a back pad 210. The back insulating layer 211 and the back pad 210 may refer to the second bonding insulating layer 211 and the second bonding pad 210, respectively.

The front protective layer 640 may be disposed under the circuit layer 620. The front protective layer 640 may include a front insulating layer 641 and a front pad 642. The front pad 642 may be electrically connected to the back pad 210 via the inner wiring 622 and the through-via 630. The front pad 642 may provide a connection terminal via which the second semiconductor structure S2 and the first semiconductor chip S1 may be electrically connected to an external device. A separate connection member 650 (e.g., a solder ball, a copper pillar, or the like) may be disposed under the front pad 642. However, embodiments of the present disclosure are not limited thereto, and the second semiconductor structure S2 may be hybrid-bonded to another structure (e.g., a silicon interposer) without a connection member.

Each of the back insulating layer 211 and the front insulating layer 641 may include at least one of silicon oxide, silicon nitride, silicon oxynitride, silicon carbide, silicon oxycarbide, and silicon carbonitride. Each of the back pad 210 and the front pad 642 may include the above-described metal material similar to that of the inner wiring 622, but may not necessarily include the same type of metal material as that of the inner wiring 622. The back insulating layer 211 may include an insulating material that may be boded to the first bonding insulating layer 231 of the first semiconductor chip S1, for example, at least one of silicon oxide, silicon nitride, silicon oxynitride, silicon carbide, silicon oxycarbide, and silicon carbonitride. In a similar manner, the back pad 210 may include a conductive material that may be bonded to the second bonding pad 230 of the first semiconductor chip S1, for example, one of copper (Cu), nickel (Ni), gold (Au), and silver (Ag), or an alloy thereof.

The first semiconductor chip S1 may include the second semiconductor substrate 510, the circuit layer 520, and the element layer 530.

The element layer 530 may be disposed on the front surface of the second semiconductor substrate 510 and may include individual elements constituting an integrated circuit. The inner wiring 613 in the back protective layer 611 and 211 may electrically connect the individual elements and the through-via 630 to each other. The individual elements may include a FET such as planar FET or FinFET, a flash memory, a memory element such as DRAM, SRAM, EEPROM, PRAM, MRAM, FeRAM, or RRAM, a logic element such as AND, OR, or NOT, and various active elements and/or passive elements such as systems LSI, CIS, and MEMS.

When each of the individual elements is a MRAM element, each of the individual elements may include a magnetic memory device including the memory structure MST and the upper contact wiring 247 as described with reference to FIGS. 1 to 17.

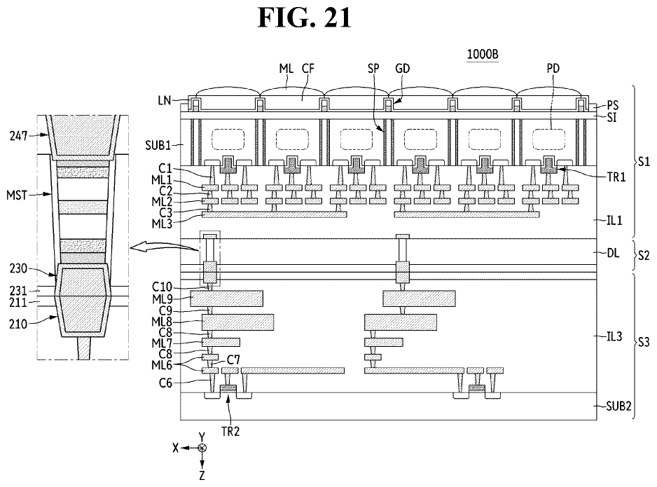

FIG. 21 is a cross-sectional view of a semiconductor structure according to some embodiments. For convenience, in FIG. 21, descriptions duplicate with those set forth above with reference to FIGS. 7 to 20 will be omitted.

Referring to FIG. 21, a semiconductor package 1000B according to some embodiments may include a first chip S1, a second chip S2, and a third chip S3 stacked in the third direction Z. The semiconductor package 1000B according to some embodiments may include an image sensor. The image sensor may sense an image of a sensing target using light to generate an image signal. The generated image signal may be, for example, a digital signal. However, an embodiment according to the technical idea of the present disclosure is not limited thereto.

A plurality of pixels (or unit pixels) may be arranged in a two-dimensional array form while being disposed on an upper surface of the first chip S1. The second chip S2 may include a memory area MR. The third chip S3 may include a logic area. The second chip S2 and the third chip S3 may be disposed under the first chip S1 and may be electrically connected to the first chip S1. A pixel signal transmitted from the first chip S1 may be transmitted to the logic area of the third chip S3. Logic elements may be disposed in the logic area LR of the third chip S3. The logic elements may include circuits for processing the pixel signal from the pixels.

The memory area may include the magnetic memory device including the memory structure MST as described with reference to FIGS. 1 to 17. The memory structure MST of the second chip S2 may be used as an image buffer memory for storing a frame image.

For example, one pixel group may include a plurality of pixels. A plurality of pixels may share a color filter having one color with each other. The image sensor may receive an image signal output from one pixel group and perform image signal processing thereon.

One pixel may include one microlens ML and one photoelectric conversion layer PD.

The first chip S1 may include a semiconductor substrate SUB1, a photoelectric conversion layer PD, a first transistor TR1, a pixel isolation pattern SP, etc.

The first semiconductor substrate SUB1 may be made of, for example, bulk silicon or silicon-on-insulator (SOI). The semiconductor substrate SUB1 may be a silicon substrate, or may include a material other than silicon, for example, silicon germanium, indium antimonide, lead telluride compound, indium arsenide, indium phosphide, gallium arsenide, or gallium antimonide. Alternatively, the first semiconductor substrate SUB1 may be formed by forming an epitaxial layer disposed on a base substrate. The first semiconductor substrate SUB1 may include a front surface and a rear surface opposite to each other. In some embodiments, the rear surface of the first semiconductor substrate SUB1 may be a light-receiving surface on which light is incident.

In some embodiments, the first transistor TR1 may be disposed on the front surface of the first semiconductor substrate SUB1. The first transistor TR1 may include, for example, at least some of various transistors (e.g., a transfer transistor, a reset transistor, a source follower transistor, and a select transistor) constituting the unit pixel of the image sensor.

The pixel isolation pattern SP may be disposed in the first semiconductor substrate SUB1. The pixel isolation pattern SP may define each of a plurality of unit pixel areas in which the photoelectric conversion layer PD is formed. The photoelectric conversion layers PD may be two-dimensionally arranged in a plan view. For example, the pixel isolation pattern SP may be formed in a grid manner in a plan view so as to isolate the photoelectric conversion layers PD from each other. The pixel isolation pattern SP may be formed by filling a deep trench formed by patterning the first semiconductor substrate SUB1 with an insulating material.

The photoelectric conversion layer PD may be formed in the first semiconductor substrate SUB1. The photoelectric conversion layer PD may generate charges in proportion to an amount of light incident from the outside. The photoelectric conversion layer PD may be formed by doping impurities in the first semiconductor substrate SUB1.

The first chip S1 may include a surface insulating layer SI, a passivation layer PS, a grid pattern GD, a color filter CF, and a microlens ML.

The surface insulating layer SI may be stacked on the back surface of the first semiconductor substrate SUB1. The passivation layer PS may be stacked on the surface insulating layer SI. The grid pattern GD, the color filter CF, and the microlens ML may be disposed on an area defined by the surface insulating layer SI.

The color filter CF may be formed on the surface insulating layer SI. The color filters CF may be arranged in a corresponding manner to the photoelectric conversion layers PD. The color filters CF may be two-dimensionally arranged in a plan view. The microlens ML may be formed on the color filter CF. The microlenses ML may be arranged in a corresponding manner to the unit pixels. The microlens ML may have a convex shape and may have a predetermined radius of curvature. Accordingly, the microlens ML may condense light incident thereto on the photoelectric conversion layer PD. The microlens ML may include, for example, a light-transmitting resin. However, embodiments of the present disclosure are not limited thereto.

The grid pattern GD may be formed between the color filters CF. The grid pattern GD may be formed on the surface insulating layer SI. The grid pattern GD may include, for example, a metal pattern and a low refractive index pattern.

A first liner LN may be formed on the surface insulating layer SI and the grid pattern GD. The first liner LN may extend along surfaces of the surface insulating layer SI and the grid pattern GD. The first liner LN may include, for example, aluminum oxide. However, embodiments of the present disclosure are not limited thereto.

Although not specifically shown, a second liner extending along the surface of the microlens ML may be further included. The second liner may include, for example, an inorganic oxide film (e.g., made of silicon oxide, titanium oxide, zirconium oxide, hafnium oxide, and combinations thereof). However, embodiments of the present disclosure are not limited thereto.

The first chip S1 may include an inter-wiring insulating layer IL1, and a plurality of metal layers ML1, ML2, and ML3 and a plurality of contacts C1 to C3 disposed in the inter-wiring insulating layer IL1. The inter-wiring insulating layer IL1 may be formed on one surface of the first semiconductor substrate SUB1. That is, the first transistor TR1 may be disposed at a boundary between the first semiconductor substrate SUB1 and the inter-wiring insulating layer IL1.

Each of the metal layers ML1, ML2, and ML3 and the contacts C1 to C3 may include a conductive material. For example, each of the plurality of metal layers ML1, ML2, and ML3 and the plurality of contacts C1 to C3 may include a metal material such as copper or lead. The number of layers, number, and arrangement of the plurality of metal layers ML1, ML2, and ML3 and the plurality of contacts C1 to C3 are only examples, and are not limited to those shown.

The first chip S1 may include the upper contact wiring 247 as described with reference to FIGS. 1 to 17. The upper contact wiring 247 may be electrically connected to at least one of the plurality of metal layers ML1, ML2, and ML3 and the plurality of contacts C1 to C3.

The second chip S2 may include the first bonding pad 230 and the first bonding insulating layer 231. The second chip S2 may include an interlayer insulating layer DL and the memory structure MST as described with reference to FIGS. 1 to 17 as disposed in the interlayer insulating layer DL.

The third chip S3 may be disposed under the second chip S2. The third chip S3 and the second chip S2 may be in contact with each other at a bonding surface therebetween. The second chip S2 and the third chip S3 may be connected to each other via the first bonding pad 230 and the second bonding pad 210.

The third chip S3 may include a second semiconductor substrate SUB2, a second transistor TR2, an inter-wiring insulating layer IL3, the second bonding pad 210, and the second bonding insulating layer 211. The second bonding pad 210 may be formed in the second bonding insulating layer 211. A plurality of metal layers ML6 to ML9 and a plurality of contacts C6 to C10 may be formed in the inter-wiring insulating layer IL3. The second bonding pad 210 may be electrically connected to at least one of the plurality of metal layers ML6 to ML9 and the plurality of contacts C6 to C10. The number of the layers, number, and arrangement of the plurality of metal layers ML6 to ML9 and the plurality of contacts C6 to C10 are only examples, and are not limited to those shown.

The second semiconductor substrate SUB2 may be made of, for example, bulk silicon or silicon-on-insulator (SOI). The second semiconductor substrate SUB2 may be a silicon substrate, or may include a material other than silicon, for example, silicon germanium, indium antimonide, lead telluride compounds, indium arsenide, indium phosphide, gallium arsenide, or gallium antimonide.

The second transistor TR2 may be disposed on the front surface of the second semiconductor substrate SUB2. The second transistor TR2 may be implemented as, for example, logic elements for controlling the operation of the image sensor. The second transistor TR2 and the second bonding pad 210 may be electrically connected to each other via the plurality of metal layers ML6 to ML9 and the plurality of contacts C6 to C10 of the third chip S3.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A magnetic memory device comprising:
a first semiconductor structure having a first bonding structure and including a substrate under the first bonding structure, and a transistor disposed on the substrate; and
a second semiconductor structure disposed on the first semiconductor structure and having a second bonding structure bonded to the first bonding structure,
wherein the second semiconductor structure includes:
a memory structure electrically connected to the transistor, and including a first electrode layer, a magnetic tunnel junction layer, and a second electrode layer sequentially stacked on the second bonding structure, and
a wiring disposed on the memory structure and connected to the second electrode layer,
wherein the memory structure includes a first area adjacent to the wiring and a second area adjacent to the second bonding structure, and
wherein in a direction parallel to an upper surface of the substrate, a width of the second area is smaller than a width of the first area.

2. The magnetic memory device of claim 1, wherein the memory structure includes a first sidewall and a second sidewall facing each other,
wherein the first sidewall extends in a first direction and defines an acute angle with respect to the upper surface of the substrate,
wherein the second sidewall extends in a second direction different from the first direction and defines an acute angle with respect to the upper surface of the substrate.

3. The magnetic memory device of claim 1, wherein the second semiconductor structure further includes:
a capping film extending along a sidewall of the memory structure; and
a mold insulating film disposed on the capping film so as to fill a space between the memory structures.

4. The magnetic memory device of claim 3, wherein the mold insulating film includes a third area adjacent to the wiring and a fourth area adjacent to the second bonding structure,
wherein in the direction parallel to an upper surface of the substrate, a width of the fourth area is greater than a width of the third area.

5. The magnetic memory device of claim 1, wherein the first electrode layer and the second electrode layer include different metal materials.

6. The magnetic memory device of claim 1, wherein the memory structure further includes:
a first barrier layer disposed between the first electrode layer and the magnetic tunnel junction layer; and
a second barrier layer disposed between the second electrode layer and the magnetic tunnel junction layer.

7. The magnetic memory device of claim 6, wherein each of the first barrier layer and the second barrier layer includes at least one of a metal and a metal oxide.

8. The magnetic memory device of claim 6, wherein the first barrier layer and the second barrier layer include different metal materials.

9. The magnetic memory device of claim 1, wherein the magnetic tunnel junction layer includes a first magnetic pattern, a tunnel barrier pattern, and a second magnetic pattern sequentially stacked between the first electrode layer and the second electrode layer.

10. The magnetic memory device of claim 1, wherein the first semiconductor structure further includes a lower wiring structure disposed between the first bonding structure and the transistor.

11. The magnetic memory device of claim 1, wherein the first bonding structure includes a first bonding pad and a first bonding insulating layer,
wherein the second bonding structure includes a second bonding pad and a second bonding insulating layer,
wherein each of the first bonding pad and the second bonding pad includes copper (Cu),
wherein each of the first bonding insulating layer and the second bonding insulating layer includes silicon carbonitride (SiCN).

12. A magnetic memory device comprising:
a substrate having an upper surface extending in a first horizontal direction and a second horizontal direction different from each other;
a first semiconductor structure disposed on the substrate, and including a transistor and a second bonding pad; and
a second semiconductor structure disposed on the first semiconductor structure, and including:
a first bonding pad bonded to the second bonding pad;
a memory structure disposed on the first bonding pad, electrically connected to the transistor, and including a first electrode layer in contact with the first bonding pad, a magnetic tunnel junction layer disposed on the first electrode layer, and a second electrode layer disposed on the magnetic tunnel junction layer; and
a wiring disposed on the second electrode layer so as to be in contact with the second electrode layer,
wherein each of a width in the first horizontal direction of the wiring and a width in the first horizontal direction of the first bonding pad decreases as each of the wiring and the first bonding pad extends toward the magnetic tunnel junction layer.

13. The magnetic memory device of claim 12, wherein the second semiconductor structure further includes:
a capping film extending along a sidewall of the memory structure; and
a mold insulating film disposed on the capping film so as to fill a space between the memory structures,
wherein a width in the first horizontal direction of the mold insulating film increases as the mold insulating film extends toward the upper surface of the substrate.

14. The magnetic memory device of claim 12, wherein the memory structure includes:
a first barrier layer disposed between the first electrode layer and the magnetic tunnel junction layer; and
a second barrier layer disposed between the second electrode layer and the magnetic tunnel junction layer.

15. The magnetic memory device of claim 12, wherein a width in the first horizontal direction of the first bonding pad increases as the first bonding pad extends toward the upper surface of the substrate,
wherein a width in the first horizontal direction of the second bonding pad decreases as the second bonding pad extends toward the upper surface of the substrate.

16. The magnetic memory device of claim 12, wherein the first bonding pad is not aligned with the second bonding pad.

17. A magnetic memory device comprising:
a substrate having an upper surface extending in a first horizontal direction and a second horizontal direction different from each other;
a logic area including a first transistor disposed on the substrate, and a first lower bonding structure disposed on the first transistor;
a memory cell area disposed on the logic area, and including:
an upper bonding structure bonded to the first lower bonding structure,
a memory structure disposed on the upper bonding structure and including a first electrode layer, a magnetic tunnel junction layer, and a second electrode layer sequentially stacked,
a bit line disposed on the memory structure and connected to the second electrode layer,
a capping film extending along a sidewall of the memory structure, and
a mold insulating film disposed on the capping film so as to fill a space between the memory structures; and
a peripheral circuit area disposed on the logic area and different from the memory cell area, and including a second transistor on the substrate and a second lower bonding structure disposed on the second transistor,
wherein a width in the first horizontal direction of the memory structure decreases as the memory structure extends toward the upper surface of the substrate,
wherein a width in the first horizontal direction of the mold insulating film increases as the mold insulating film extends toward the upper surface of the substrate.

18. The magnetic memory device of claim 17, wherein the memory structure includes a first sidewall and a second sidewall facing each other,
wherein the first sidewall defines an acute angle in a counterclockwise direction with respect to the upper surface of the substrate,
wherein the second sidewall defines an acute angle in a clockwise direction with respect to the upper surface of the substrate.

19. The magnetic memory device of claim 17, wherein the memory structure further includes:
a first barrier layer disposed between the first electrode layer and the magnetic tunnel junction layer; and
a second barrier layer disposed between the second electrode layer and the magnetic tunnel junction layer,
wherein the first barrier layer and the second barrier layer include different metal materials.

20. The magnetic memory device of claim 17, wherein the peripheral circuit area further includes a via structure disposed on the second lower bonding structure and extending through the mold insulating film.
